(19) United States
(12) Patent Application Publication
(10) Pub. No.: US 2026/0060116 A1
(43) Pub. Date: Feb. 26, 2026

(54) WIRING BOARD FOR MOUNTING SEMICONDUCTOR DEVICE, METHOD FOR PRODUCING WIRING BOARD, AND SEMICONDUCTOR DEVICE

(71) Applicant: TOPPAN HOLDINGS INC., Tokyo (JP)

(72) Inventors: Akihiro HAYASHI, Tokyo (JP); Takeshi TAMURA, Tokyo (JP)

(73) Assignee: TOPPAN HOLDINGS INC., Tokyo (JP)

(21) Appl. No.: 19/376,399

(22) Filed: Oct. 31, 2025

Related U.S. Application Data
(63) Continuation of application No. PCT/JP2024/014044, filed on Apr. 5, 2024.

(30) Foreign Application Priority Data
May 2, 2023 (JP) 2023-076068
May 2, 2023 (JP) 2023-076073

(51) Int. Cl. H01L 23/498

(52) U.S. Cl. CPC H01L 23/49838; H01L 23/49816; H01L 23/49827

(57) ABSTRACT

An object of the present invention is to provide a wiring board for mounting a semiconductor device capable of increasing the design flexibility of a 3D multilayer structure and method for producing the wiring board. One aspect is a wiring board for mounting a semiconductor device. The wiring board includes a first connection terminal area and a second connection terminal area on a semiconductor device mounting surface, in which the first connection terminal area includes a first connection terminal including a first connection pad and a solder bump, the second connection terminal area includes a second connection terminal including a second connection pad and a solder bump, and the first connection pad is covered by a solder resist layer on its side surface and a part of the top surface, whereas the second connection pad is not covered by a solder resist layer on its side surface and top surface.

### CROSS-REFERENCE TO RELATED PATENT APPLICATIONS

The present application is a Bypass Continuation of International Patent Application No. PCT/JP2024/014044, filed Apr. 5, 2024, which claims priority to and the benefit of Japanese Patent Application No. 2023-076068, filed on May 2, 2023, and Japanese Patent Application No. 2023-076073, filed on May 2, 2023. The contents of these applications are hereby incorporated by reference herein in their entireties.

### TECHNICAL FIELD

The present invention relates to a wiring board for mounting a semiconductor device used to mount an electronic component such as a semiconductor device (chip), a method for producing the wiring board, and a semiconductor device.

### BACKGROUND

Due to the increasing integration density of semiconductor devices in recent years, semiconductor device integration methods have shifted from planar integration to three-dimensional integration, and semiconductor devices having a 3D multilayer structure have received attention.

A method for mounting a semiconductor device having a 3D multilayer structure is described in Patent Literature 1. For example, during the development phase of an IC package 10 containing a new IC chip 1, an alternative IC package 20 is fabricated, and the circuit board on which the IC package 10 is mounted and the product are evaluated using the IC package 20. The IC package 20 includes two stacked IC chips 11a and 11b, an interposer substrate 12, and solder ball terminals 16 provided on the rear surface of the interposer substrate 12. Alignment of the solder ball terminals 16 with the solder ball terminals provided on the IC package 10 enables the IC package 20 to be mounted on the circuit board, allowing the circuit board and the product incorporating the circuit board to be examined.

According to Patent Literature 2, a semiconductor device 2 has bump connection electrodes 3 on the surface facing a wiring board 1, or the surface sandwiched between the wiring board 1 and the semiconductor device 2 or between two semiconductor devices 2, as well as on the opposite surface, and some or all bump connection electrodes 3 formed on one of the surfaces are electrically connected to the bump connection electrodes 3 formed on the other surface.

When a semiconductor device having a 3D multilayer structure includes a first semiconductor device mounted immediately above a wiring board for mounting a semiconductor device, with a second semiconductor device further mounted on the first semiconductor device, the electrical connection between the second semiconductor device and the wiring board is to be established by wire bonding from the surface facing away from the wiring board for mounting a semiconductor device as in Patent Literature 1 or by solder ball connection via the first semiconductor device as in Patent Literature 2.

[Citation List] [Patent Literature] [PTL 1] JP 2003-289127 A [PTL 2] JP2 002-261232 A

These conventional mounting (connection) methods need the area of the second semiconductor device to be smaller than the area of the first semiconductor device. The limited size of the semiconductor device makes it difficult to increase the design flexibility of the 3D multilayer structure.

The present invention has been made in view of the above issue, and an object of the disclosure is to provide a wiring board for mounting a semiconductor device capable of increasing the design flexibility of the 3D multilayer structure and a method for producing the wiring board.

### SUMMARY OF THE INVENTION

An aspect of the present invention for achieving the above object is a wiring board for mounting a semiconductor device. The wiring board includes a first connection terminal area and a second connection terminal area on a semiconductor device mounting surface, in which the first connection terminal area includes a first connection terminal including a first connection pad and a solder bump, the second connection terminal area includes a second connection terminal including a second connection pad and a solder bump, and the first connection pad is covered by a solder resist layer on its side surface and a part of the top surface, whereas the second connection pad is not covered by a solder resist layer on its side surface and top surface.

### Advantageous Effects of the Invention

The wiring board for mounting a semiconductor device according to the present invention can increase the design flexibility of the 3D multilayer structure.

Other objects, configurations, and advantages will become apparent from the following detailed description.

### BRIEF DESCRIPTION OF THE DRAWINGS

FIG. 1 is a diagram illustrating an example of a cross section of a wiring board for mounting a semiconductor device according to a first embodiment of the present invention.

FIGS. 2A-2G are a diagram illustrating an example of a method for producing a core substrate according to the present invention.

FIGS. 3A-3F are a diagram illustrating a method for producing a wiring board according to the first embodiment of the present invention.

FIGS. 4A-4D are a diagram illustrating the method for producing the wiring board according to the first embodiment of the present invention.

FIG. 5 is a diagram illustrating the method for producing the wiring board according to the first embodiment of the present invention.

FIG. 6 is a diagram illustrating an example of a mounted state.

FIG. 7 is a diagram illustrating an example of a second connection terminal area according to the first embodiment of the present invention.

FIG. 8 is a diagram illustrating an example of the second connection terminal area according to the first embodiment of the present invention.

FIG. 9 is a diagram illustrating an example of the second connection terminal area according to the first embodiment of the present invention.

FIG. 10 is a diagram illustrating an example of the second connection terminal area according to the first embodiment of the present invention.

FIG. 11 is a diagram illustrating an example of the second connection terminal area according to the first embodiment of the present invention.

FIG. 12 is a diagram illustrating an example of the second connection terminal area according to the first embodiment of the present invention.

FIG. 13 is a diagram illustrating an example of a cross section of a wiring board according to a second embodiment of the present invention.

FIG. 14 is a diagram illustrating an example of a cross section of a wiring board according to a third embodiment of the present invention.

FIG. 15 is a diagram illustrating an example of a cross section of a wiring board according to a fourth embodiment of the present invention.

FIG. 16 is a diagram illustrating an example of a mounted state.

FIG. 17 is a diagram illustrating an example of a cross section of a conventional wiring board for mounting a semiconductor device.

FIGS. 18A-18D are a diagram illustrating a method for producing a wiring board according to a fifth embodiment of the present invention.

FIGS. 19A-19C are a diagram illustrating the method for producing the wiring board according to the fifth embodiment of the present invention.

FIG. 20 is a diagram illustrating an example of a mounted state.

FIG. 21 is a diagram illustrating an example of a second connection terminal area according to the fifth embodiment of the present invention.

FIG. 22 is a diagram illustrating an example of the second connection terminal area according to the fifth embodiment of the present invention.

FIG. 23 is a diagram illustrating an example of the second connection terminal area according to the fifth embodiment of the present invention.

FIG. 24 is a diagram illustrating an example of the second connection terminal area according to the fifth embodiment of the present invention.

FIG. 25 is a diagram illustrating an example of the second connection terminal area according to the fifth embodiment of the present invention.

FIG. 26 is a diagram illustrating an example of the second connection terminal area according to the fifth embodiment of the present invention.

### DETAILED DESCRIPTION

Embodiments will now be described with reference to the drawings. For convenience of explanation, the dimensions in the drawings may not be to scale, and a part of layers or a structure may not be illustrated in the drawings.

A wiring board according to the present disclosure includes a core substrate having a first surface and a second surface opposite to the first surface, and layers having the same function are symmetrically placed on these surfaces. Thus, the top surface of a layer refers to the surface farther from the core substrate, whereas the bottom surface of a layer refers to the surface closer to the core substrate. Furthermore, the upper layer refers to a layer positioned farther away from the core substrate, whereas the lower layer refers to a layer positioned closer to the core substrate.

### CONVENTIONAL EXAMPLE

FIG. 17 is a diagram illustrating an example of a cross section of a conventional wiring board 900 for a mounting semiconductor device. In this figure, the surface on which first connection terminals 24 are formed is the side on which a semiconductor device is to be mounted, and the surface on which solder bumps 20 are formed is the side of the wiring board 900 to be connected to, for example, a motherboard. On the surface on which a semiconductor device is to be mounted, the first connection terminals 24 are formed to have a common height. Thus, when semiconductor devices are mounted in a stack, the mounting surface cannot be efficiently used.

### First Embodiment

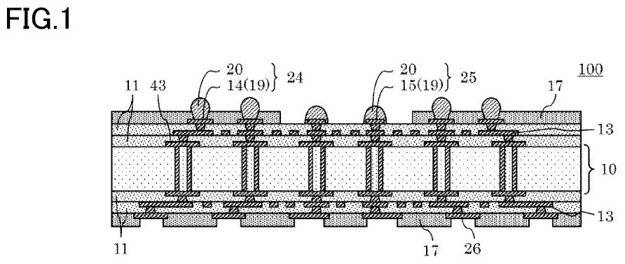

A first embodiment is described with reference to FIGS. 1 to 12. FIG. 1 is a diagram illustrating an example of a cross section of a wiring board for mounting a semiconductor device according to the first embodiment of the present invention.

### Structure of Wiring Board

A wiring board 100 for mounting a semiconductor device includes a core substrate 10, multiple insulating resin layers 11, and multiple conductor layers 13. A pad portion 43 is formed on the core substrate 10 and electrically connected to the conductor layer 13 stacked over the core substrate 10.

### Insulating Resin Layer

The insulating resin layers 11 are each composed of a thermosetting resin, a thermoplastic resin, a photosensitive resin, or a resin made by mixing at least two of them. Examples include an epoxy resin, an acrylic resin, a phenolic resin, a melamine resin, a silicone resin, a polyimide resin, a polyphenylene ether resin, a maleimide resin, a liquid crystal polymer, a fluororesin, or a resin obtained by combining at least two of these, and the resin may contain an inorganic filler or an organic filler.

### Conductor Layer

The conductor layers 13 each include, as described below, a seed layer 13a and a plating layer 13b arranged sequentially from the lower insulating resin layer 11. A resist pattern 16 is used for plating. After the resist pattern 16 is stripped, the exposed seed layer 13a is etched away to form the multiple conductor layers 13. Although the conductor layers 13 can include various patterns such as traces, vias, pads, shields, grounds, and dummies, FIG. 1 illustrates traces, vias, and pad portions. Adjacent conductor layers 13 are spaced apart in the planar direction of the insulating resin layer 11.

### Seed Layer

The seed layer 13a is stacked on the insulating resin layer 11. Although the seed layer 13a may be formed from any material, metal materials such as Cu, Pd, Al, Sn, Ni, and Cr can be used for formation by electroless plating. For formation by sputtering, for example, materials containing at least one of Cu, Ni, Al, Ti, Cr, Mo, W, Ta, Au, Ir, Ru, Pd, Pt, AlSi, AlSiCu, AlCu, NiFe, ITO (indium tin oxide), IZO (indium zinc oxide), AZO (aluminum-doped zinc oxide), ZnO, PZT (lead zirconium titanate), TiN, Cu₃N₄, and Cu alloy can be used.

### Plating Layer

The plating layer 13b is stacked on the top surface of the seed layer 13a. The plating layer 13b is mainly composed of metal and is not restricted to any particular kind. The plating layer 13b can be composed of, for example, materials containing at least one of Cu, Cu alloy, Ag, Ag alloy, Sn, Pd, Au, Ni, Cr, Pt, and Fe.

### Solder Resist Layer

A solder resist layer 17 is composed of a thermosetting resin, a thermoplastic resin, a photosensitive resin, or a resin made by mixing at least two of these. Examples include an epoxy resin, an acrylic resin, a phenolic resin, a melamine resin, a silicone resin, a polyimide resin, a polyphenylene ether resin, a maleimide resin, a liquid crystal polymer, a fluororesin, or a resin obtained by combining at least two of these, and the resin may contain an inorganic filler or an organic filler.

### Connection Terminal

The surface on which a first connection terminal 24 and a second connection terminal 25 are formed is, for example, connected with a semiconductor device. The first connection terminal 24 includes a first connection pad 14 (or a surface-treated layer 19) and a solder bump 20. The second connection terminal 25 includes a second connection pad 15 (or a surface-treated layer 19) and a solder bump 20. As illustrated, the top of the first connection terminal 24 is positioned farther from the core substrate 10 than the top of the second connection terminal 25.

On a pad portion 26, a solder bump 20 is formed for connection to, for example, a motherboard.

### Method for Producing Wiring Board

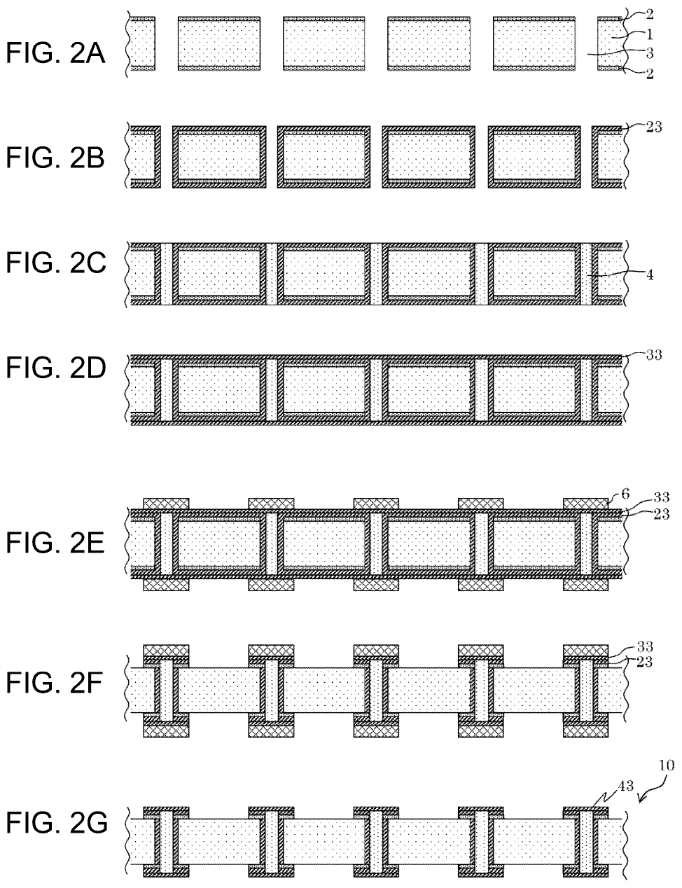

A method for producing the wiring board 100 according to the first embodiment is described. First, a process for producing the core substrate 10 is described with reference to FIGS. 2A-2G. FIGS. 2A-2G are a diagram illustrating an example of a method for producing the core substrate 10 according to the present invention.

### Production of Core Substrate

First, a core resin 1 laminated with copper foil 2 on both surfaces is drilled with a tool such as a drill to create a through hole 3 for electrically connecting the front and rear surfaces (FIG. 2A).

Next, a conductor layer 23 is formed on the surface of the copper foil 2 and the wall surface of the through hole 3 by electroless plating and electroplating (FIG. 2B). The electroless plating for the conductor layer 23 can be achieved using the same materials as the seed layer 13a described later. The electroplating for the conductor layer 23 can be achieved using the same materials as the plating layer 13b described later.

Next, the through hole 3 is filled with a hole-filling resin 4. The unnecessary part of the hole-filling resin 4 protruding from the through hole 3 is removed by, for example, buffing (FIG. 2C). This step is omitted when the through hole 3 is completely filled by plating in the step in FIG. 2B.

Next, a conductor layer 33 is formed across the entire surface by electroless plating and electroplating (FIG. 2D). This step may be omitted when the through hole 3 is completely filled by plating in the step in FIG. 2B or no conductor layer 33 is needed over the hole-filling resin.

Next, resist is applied or laminated, and a resist pattern 6 is formed by photolithography over parts of the conductor layers 23 and 33 to be retained as conductors (FIG. 2E). The resist used here is photosensitive.

Next, the parts of the conductor layers 23 and 33 over which no resist pattern 6 is formed are removed by etching. The remaining parts of the conductor layers 23 and 33 serve as multiple conductor pieces (FIG. 2F).

Next, the resist pattern 6 is removed to yield the core substrate 10 including the pad portion 43 (FIG. 2G). The pad portion 43 is, as described below, electrically connected to the conductor layer 13 stacked on the core substrate 10.

The method described above for producing the core substrate 10 is only an example, and another production method may also be used.

### Production of Insulating Resin Layer and Conductor Layer

The following describes a process for fabricating (producing) the wiring board 100 by stacking multiple insulating resin layers and conductor piece layers (conductor layers 13) over the produced core substrate 10. Note that the insulating resin layers and the conductor layers are stacked on both surfaces of the core substrate 10.

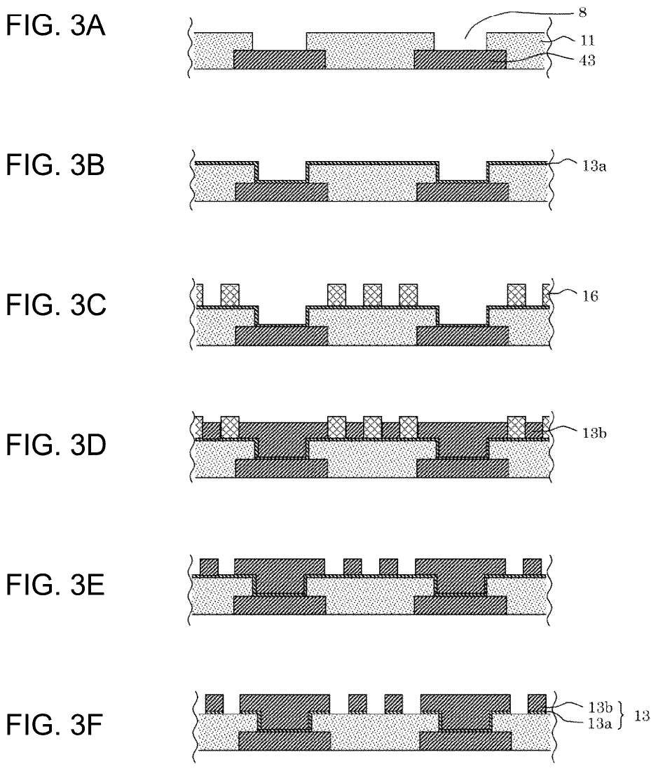

FIGS. 3A-3F to 5 are diagrams illustrating a method for producing a wiring board according to the first embodiment of the present invention. Note that the core resin 1 of the core substrate 10 is not illustrated. These figures illustrate the wiring layer formed on the core substrate surface facing upward in the vertical direction when the core substrate 10 is mounted.

First, the insulating resin layer 11 is formed on the core substrate 10 and subjected to UV, CO₂, or other laser irradiation when the layer is a thermosetting resin or subjected to photolithography when the layer is a photosensitive resin, to form a via opening 8, exposing the lower pad portion 43 (FIG. 3A). The residual resin in the via opening 8 is removed using permanganate-based or other desmearing solutions or plasma-based or other dry desmearing processes.

Next, the seed layer 13a is formed by electroless plating or sputtering on the top surface of the insulating resin layer 11, the wall surface of the via opening 8, and the part of the pad portion 43 corresponding to the bottom surface of the via opening 8 (FIG. 3B).

Next, resist is applied or laminated onto the seed layer 13a and subjected to exposure and development to form the resist pattern 16 corresponding to the pattern of the plating layer 13b (FIG. 3C). The resist used here is photosensitive.

Next, the plating layer 13b is formed by electroplating on the seed layer 13a on which the resist pattern 16 is formed (FIG. 3D).

Next, the resist pattern 16 is removed (FIG. 3E).

Next, the part of the seed layer 13a exposed by the removal of the resist pattern 16 (the part of the seed layer 13a not covered by the plating layer 13b) is removed by etching (FIG. 3F).

Next, an insulating resin layer 11 is stacked to cover the conductor layer 13 and the lower insulating resin layer 11. When a circuit with an intended number of layers is formed, this step is omitted.

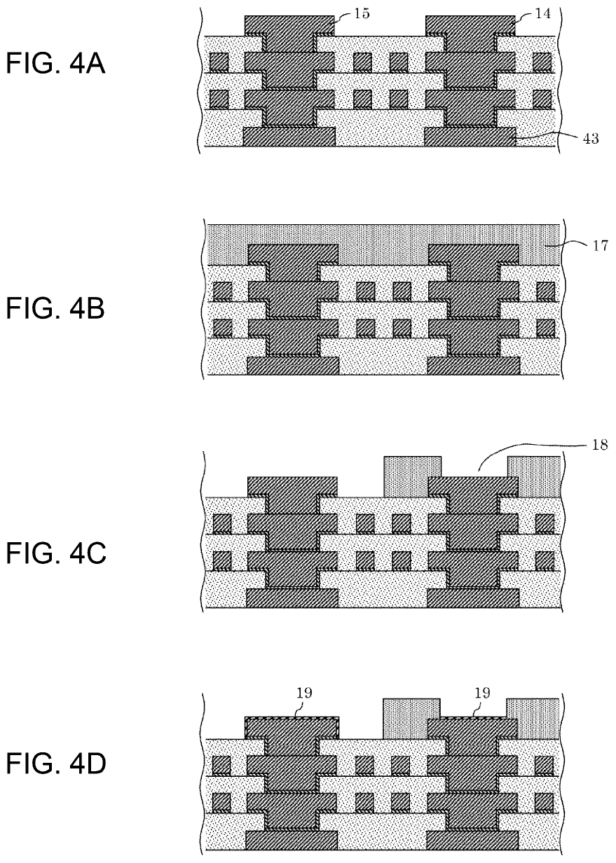

The above steps are repeated until a circuit with an intended number of layers is formed (FIG. 4G).

After the circuit with the intended number of layers is formed, the solder resist layer 17 is applied or laminated onto the outermost layer (FIG. 4B).

Subsequently, the part of the solder resist layer 17 surrounding the second connection pad 15 is removed and an opening 18 is formed in the part of the solder resist layer 17 over the first connection pad 14 by, for example, photolithography (FIG. 4C). The solder resist layer 17 is, for example, a photosensitive epoxy resin and may contain an inorganic filler. The part of the solder resist surrounding the second connection pad 15 is removed and the opening 18 is formed in the part of the solder resist layer 17 over the first connection pad 14 by, for example, UV or CO₂ laser irradiation or photolithography. In this state, the side surface and part of the top surface of the first connection pad 14 are covered with the solder resist layer 17, whereas the side surface and the top surface of the second connection pad 15 are not covered with the solder resist layer 17.

Next, a surface-treated layer 19 is formed on the first connection pad 14 within the opening 18 in the solder resist layer and the top surface and the side surface of the second connection pad 15 (FIG. 4C).

After the above process, by forming the solder bumps 20 over the first connection pad 14 within the opening 18 in the solder resist layer 17 and the second connection pad 15, the wiring board 100 can be formed with a first connection terminal area 124 and a second connection terminal area 125 on a semiconductor device mounting surface (FIG. 5). In the first connection terminal area 124, the first connection terminal 24 including the first connection pad 14 and the solder bump 20 is formed. In the second connection terminal area 125, the second connection terminal 25 including the second connection pad 15 and the solder bump 20 is formed. In the first connection terminal area 124, at least one first connection terminal 24 is formed in accordance with a first pattern width (pitch). In the second connection terminal area, at least one second connection terminal is formed in accordance with a second pattern width. The first pattern width and the second pattern width can be set to a predetermined length. The first pattern width and the second pattern width may be the same length or different lengths. Solder bumps 20 can be formed by screen printing when soldering paste is used. When solder balls are used, after screen printing of flux, solder balls are mounted by means of ball placement and melted during reflow to form solder bumps. The solder bump 20 in the first connection terminal 24 is connected to the surface of the first connection pad 14 exposed through the opening in the solder resist layer 17, whereas the solder bump 20 in the second connection terminal 25 is connected to the front surface and the side surface of the second connection pad 15. In this case, the solder bump 20 over the second connection pad 15 wets and spreads across the entire top surface of the pad or also along the side surface, and as a result, the height H1 of the solder bump over the first connection pad 14 and the height H2 of the solder bump over the second connection pad 15 satisfy the relationship, H1>H2.

The pad diameter of the first connection pad 14 is denoted by P1, and the pad diameter of the second connection pad 15 is denoted by P2. The term “pad diameter” is not limited to circular connection pads, but can also be used to refer to the sizes of connection pads having other shapes. When the wiring board 100 is viewed from a direction perpendicular to the semiconductor device mounting surface, the diameter of the first connection pad 14 (the opening size of the solder resist layer 17 on the first connection pad 14) can be different from the diameter of the second connection pad 15. This structure enables a difference to be created between the height H1 of the solder bump over the first connection pad 14 and the height H2 of the solder bump over the second connection pad 15.

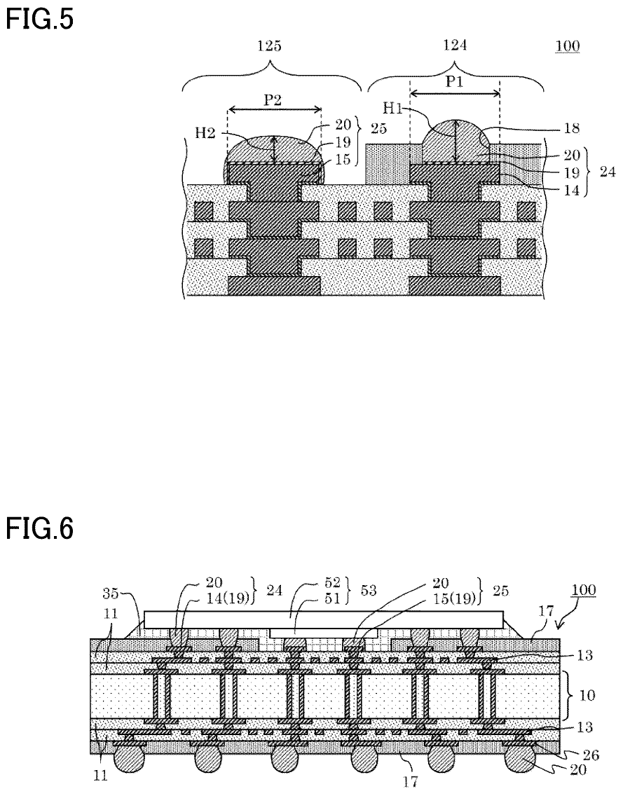

FIG. 6 is a diagram illustrating an example of a mounted state. In this illustrated state, a 3D semiconductor device 53 (silicon chip) is mounted on the wiring board 100. This 3D semiconductor device 53 may include, for example, multiple stacked (3D-integrated) semiconductor devices or a single semiconductor device having a step in the mounting surface, with the electrode terminals electrically connected (flip-chip bonded) to the corresponding first connection terminals 24 and second connection terminals 25 on the wiring board 100 via conductive materials such as the solder bumps 20. Furthermore, the space between the mounted 3D semiconductor device 53 and the wiring board 100 is filled with an underfill resin 35 such as a thermosetting epoxy resin, and mechanical bonding is established between the 3D semiconductor device 53 and the wiring board 100 by thermal curing. In the production process, multiple unit regions for mounting 3D semiconductor devices 53 may be formed on the core substrate 10. In such a case, the unit regions are separated into individual pieces by, for example, dicing to form wiring boards 100.

In the illustrated 3D semiconductor device 53, a second semiconductor device 52 is mounted on a first semiconductor device 51. The wiring board 100 is electrically connected to the second semiconductor device 52 via the first connection terminal 24. The wiring board 100 is also electrically connected to the first semiconductor device 51 via the second connection terminal 25. The first semiconductor device 51 and the second semiconductor device 52 are in direct contact and electrically connected with each other.

The 3D semiconductor device 53 is composed of the first semiconductor device 51 and the second semiconductor device 52, with a single step formed in a direction perpendicular to the mounting surface. However, it is sufficient to have at least one step, and two or more steps may also be provided. That is, the 3D semiconductor device may be implemented by stacking two or more semiconductor devices. For example, the step can be formed using the same method as illustrated in FIGS. 3A-3F to 5 for the solder resist layer 17.

Although the illustrated solder bump 20 is columnar, the shape is not limited to this. After mounting, the solder bump can be cylindrical or barrel-shaped.

On the side opposite to the mounting surface for the 3D semiconductor device 53, a solder bump 20 used as an external connection terminal is formed on the part of a pad portion 26 exposed from a solder resist layer 17 after the mounting of the 3D semiconductor device 53. The wiring board 100 is mounted on, for example, a motherboard via the solder bump 20.

### Placement of Second Connection Terminal Area

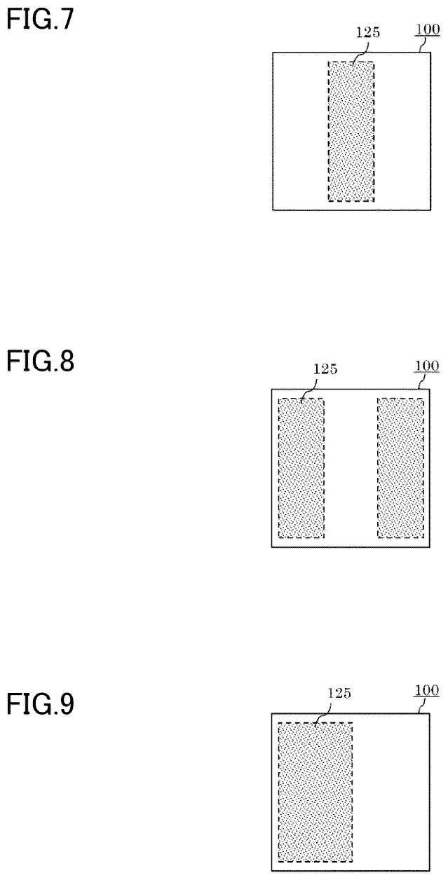

Placement examples of the second connection terminal area 125 are illustrated in FIGS. 7 to 12. FIGS. 7 to 12 are diagrams illustrating examples of the second connection terminal area according to the first embodiment of the present invention. FIGS. 7 to 12 are views of the wiring board 100 as seen from the semiconductor device mounting side in the mounted state.

FIG. 7 illustrates a rectangular second connection terminal area 125 placed at the central part of the wiring board 100. The second connection terminal area 125 is formed along two opposite sides of the four sides of the wiring board 100.

Note that the area of the wiring board 100 other than the second connection terminal area 125 includes the first connection terminal area 124. The same applies to FIGS. 8 to 12.

FIG. 8 illustrates a second connection terminal area 125 divided into two regions. The divided regions resulting from the second connection terminal area 125 are rectangular, and the rectangles have the same area.

FIG. 9 illustrates a second connection terminal area 125 occupying about half the area of the wiring board 100.

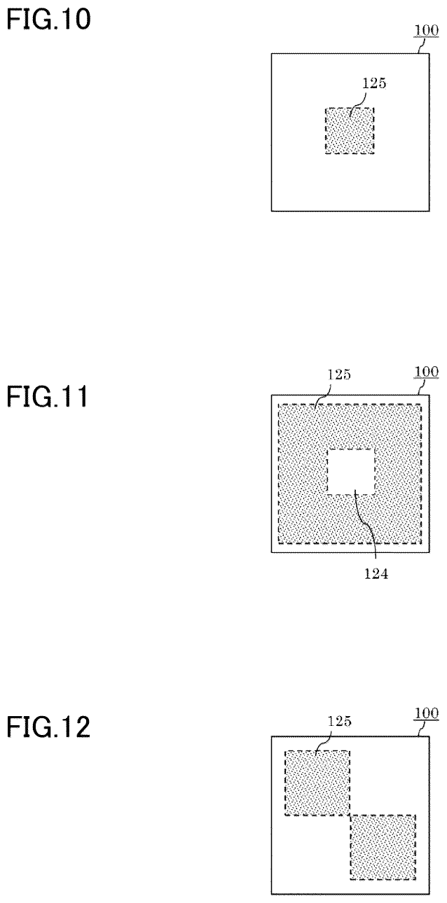

FIG. 10 illustrates a rectangular second connection terminal area 125 formed at a position coinciding with the center of gravity of the wiring board 100. The second connection terminal area 125 is geometrically similar to the wiring board 100.

FIG. 11 illustrates a second connection terminal area 125 formed to surround the region including a first connection terminal area 124.

FIG. 12 illustrates a second connection terminal area 125 divided into two regions.

The two regions are rectangular and share a common vertex.

The illustrated second connection terminal areas 125 are examples, and the area can have various other forms depending on the size and shape of the 3D semiconductor device 53. For example, although the wiring board 100 is illustrated as a square, the wiring board 100 can also have non-square shapes. Furthermore, the placement of the first connection terminal area 124 and the second connection terminal area 125 may be exchanged.

### Example 1

In Example 1, example formation of the first connection terminal 24 and the second connection terminal 25 according to the first embodiment is described.

First, a copper-clad laminate (manufactured by Showa Denko Materials Co., Ltd.) was laminated with an interlayer insulating resin (manufactured by Ajinomoto Co., Inc.), followed by a permanganate-based desmearing process without forming a via opening.

After the desmearing process, the interlayer insulating resin was covered with an electroless copper plating layer. On the electroless copper plating layer, dry film resist (manufactured by Showa Denko Materials Co., Ltd.) was laminated, exposed, and developed to form a connection pad pattern. After electrolytic copper plating, the dry film resist was stripped, and the part of the electroless copper plating layer not covered by the electrolytic copper plating was etched to form a connection pad with a diameter of about 180 μm.

Next, the copper surface is roughened using a roughening liquid (manufactured by MEC COMPANY LTD.). After the roughening treatment, dry film solder resist (manufactured by Showa Denko Materials Co., Ltd.) is laminated under vacuum, exposed using a laser direct imaging machine, and spray developed. In this process, an opening was formed in the solder resist layer for a first connection pad portion, whereas the solder resist was removed for a second connection pad portion. This opening was formed in the solder resist layer with a bottom diameter of about 80 μm.

Next, solder balls (manufactured by Senju Metal Industry Co., Ltd.) were mounted on the first and second connection pads and reflowed to form first and second connection terminals. The solder balls have a diameter of, for example, 70 μm.

As a result of measuring the height difference between the formed first and second connection terminals using a laser interferometer, the greatest difference between the first connection terminal and the second connection terminal was about 25 μm.

### Advantages and Effects

In the wiring board 100, the first connection terminal 24 in the first connection terminal area 124 is higher than the second connection terminal 25 in the second connection terminal area 125. When semiconductor devices are mounted on the wiring board 100, with a semiconductor device mounted on the second connection terminal area 125, this structure enables another semiconductor device to be additionally mounted on the semiconductor device. In this manner, the wiring board for mounting a semiconductor device according to the present disclosure can increase the design flexibility of the 3D multilayer structure.

### Second Embodiment

A second embodiment is different from the first embodiment in that the pad diameter of the second connection pad 15 has been changed. In the following description, components identical or equivalent to those in the first embodiment described above are designated with the same reference numerals, and the corresponding description is simplified or omitted.

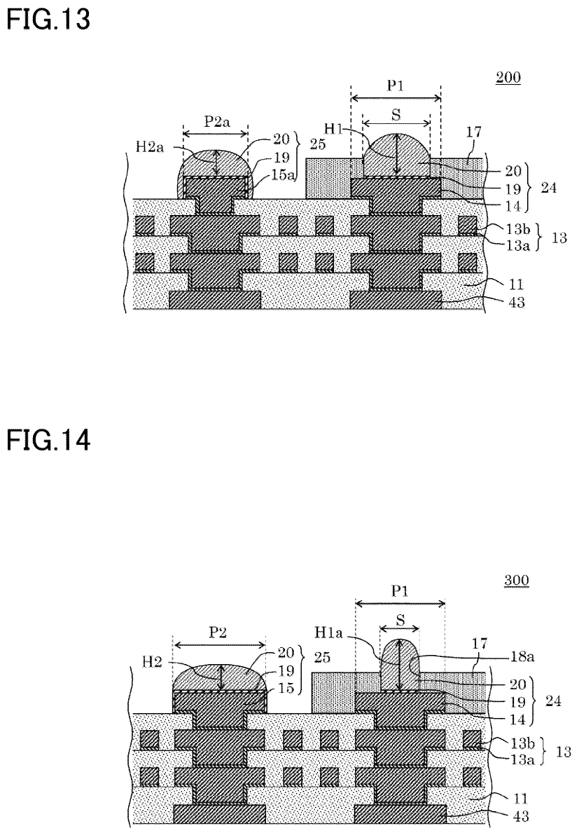

FIG. 13 is a diagram illustrating an example of a cross section of a wiring board 200 according to the second embodiment of the present invention. In this illustration, a second connection pad 15a has a pad diameter P2a smaller than the pad diameter P2 of the second connection pad 15 in the first embodiment. The solder bumps 20 are formed by screen printing or a method using solder balls, and the amount of solder used for each second connection pad 15a remains unchanged. Thus, the solder bump 20 for the second connection pad 15a has a height H2a which is greater than the height H2 of the solder bump 20 for the second connection pad 15 in the first embodiment.

Although the pad diameter P2a of the second connection pad 15a is smaller in this illustration, the pad diameter may be greater. In this case, the solder bump 20 for the second connection pad 15a has a height smaller than the height H2 of the solder bump for the second connection pad in the first embodiment.

### Advantages and Effects

As described above, when the first connection pad 14 and the second connection pad 15 are formed, adjustment of the pad diameter P2 of the second connection pad 15 can change the wetting spread width of the solder bump 20 formed later, allowing the height of the solder bump over the second connection pad to be controlled. In other words, height gap adjustment of the solder bump 20 in the first connection terminal 24 and the solder bump 20 in the second connection terminal 25 can be controlled by the diameter of the second connection pad 15. In this manner, the height of the solder bump can be changed, for example, depending on the conditions of the semiconductor device to be mounted, and thus the wiring board for mounting a semiconductor device according to the present disclosure can further increase the design flexibility of the 3D multilayer structure.

### Third Embodiment

A third embodiment is different from the first embodiment in that the opening size of the solder resist layer 17 on the first connection pad has been changed. In the following description, components identical or equivalent to those in the first embodiment described above are designated with the same reference numerals, and the corresponding description is simplified or omitted.

FIG. 14 is a diagram illustrating an example of a cross section of a wiring board 300 according to the third embodiment of the present invention. In this illustration, an opening size S for the first connection pad 14 is smaller than that in the first embodiment. This is because a smaller opening 18a is formed in the solder resist layer 17. Thus, the size of the surface-treated layer 19 on the first connection pad 14 has changed in accordance with the size of the opening 18a. The solder bumps 20 are formed by screen printing or a method using solder balls, and the amount of solder used for each first connection pad 14 remains unchanged. Thus, the solder bump 20 for the first connection pad 14 has a height H1a which is greater than the height H1 of the solder bump 20 for the first connection pad 14 in the first embodiment.

Although the opening size S of the opening 18a in the solder resist layer 17 is smaller in this illustration, the opening size S may be greater. In this case, the solder bump 20 for the first connection pad 14 has a height smaller than the height H1 of the solder bump for the first connection pad 14 in the first embodiment.

### Advantages and Effects

As described above, over the first connection pad 14, adjustment of the opening size S of the opening 18a in the solder resist layer 17 allows the height H1a of the solder bump over the first connection pad 14 to be controlled. In other words, height gap adjustment between the solder bump 20 in the first connection terminal 24 and the solder bump 20 in the second connection terminal 25 can be controlled by the opening size of the solder resist layer 17 on the first connection pad 14. In this manner, the height of the solder bump can be changed, for example, depending on the conditions of the semiconductor device to be mounted, and thus the wiring board for mounting a semiconductor device according to the present disclosure can further increase the design flexibility of the 3D multilayer structure.

### Fourth Embodiment

A fourth embodiment is different from the first embodiment in that the shape of the solder resist layer 17 has been changed. In the following description, components identical or equivalent to those in the first embodiment described above are designated with the same reference numerals, and the corresponding description is simplified or omitted.

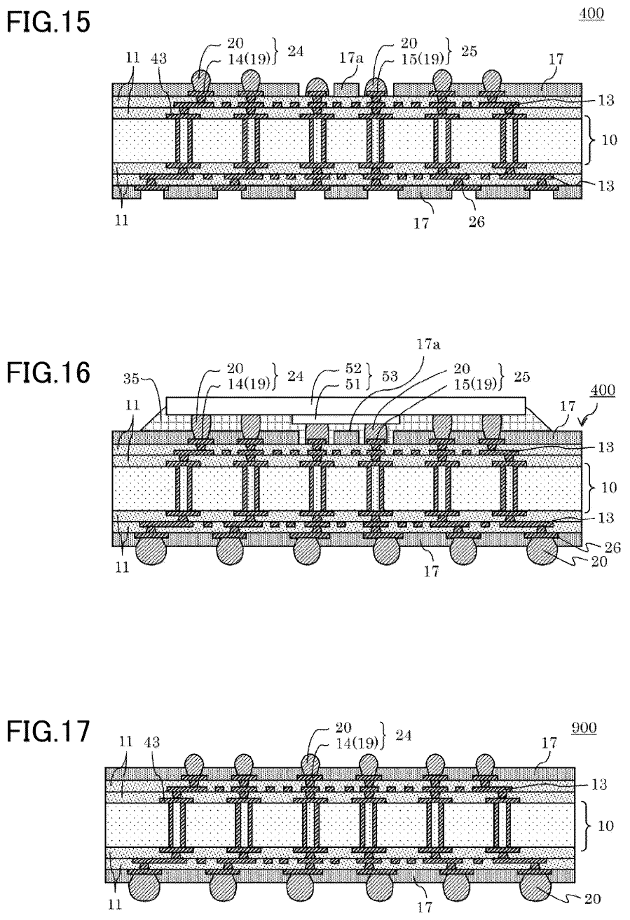

FIG. 15 is a diagram illustrating an example of a cross section of a wiring board 400 according to a fourth embodiment of the present invention. In the first embodiment, the second connection pads 15 have no solder resist layer 17 formed between them. In the present embodiment, a solder resist layer 17a remains between the second connection pads 15 instead of being removed.

FIG. 16 is a diagram illustrating an example of a mounted state. The second connection terminals 25 adjacent to the solder resist layer 17a electrically connect the first semiconductor device 51 and the wiring board 400.

### Advantages and Effects

The solder resist layer 17a remaining between the second connection pads 15 can reduce the occurrence of connection between the solder bumps 20 over the second connection pads 15, that is, solder bridging. In this manner, the solder resist layer can be formed between solder bumps, for example, depending on the conditions of the semiconductor device to be mounted, and thus the wiring board for mounting a semiconductor device according to the present disclosure can further increase the design flexibility of the 3D multilayer structure.

### Fifth Embodiment

A fifth embodiment is different from the first embodiment in that both the first connection pad 14 and the second connection pad 15 are covered with a solder resist layer. In the following description, components identical or equivalent to those in the first embodiment described above are designated with the same reference numerals, and the corresponding description is simplified or omitted.

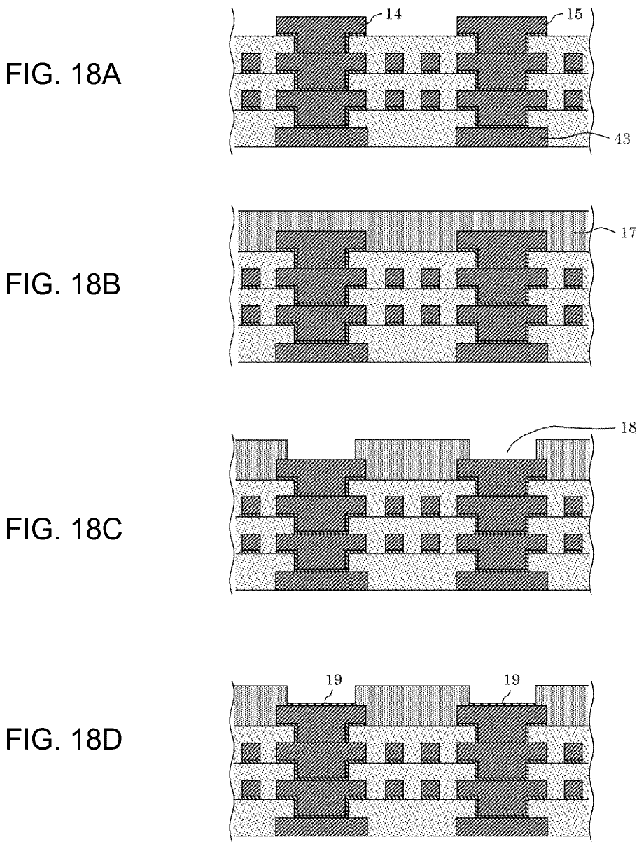

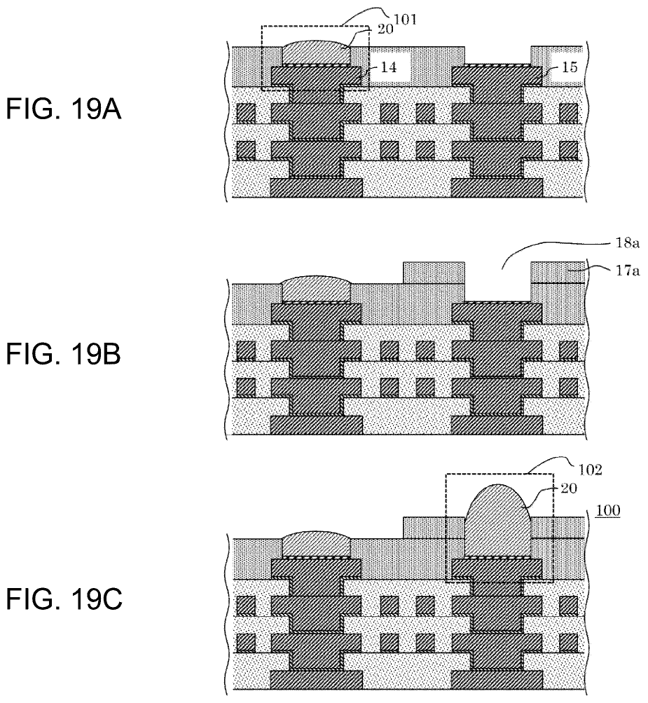

FIGS. 18A-18D to 20 are diagrams illustrating a method for producing a wiring board according to the fifth embodiment of the present invention. Note that the core resin 1 of the core substrate 10 is not illustrated in FIGS. 18A-18D and 19A-19C. These figures illustrate the wiring layer formed on the core substrate surface facing upward in the vertical direction when the core substrate 10 is mounted.

The core substrate 10 can be produced using the production method in the first embodiment described with reference to FIGS. 2A-2G. The wiring layer can also be formed using the formation method in the first embodiment described with reference to FIGS. 3A-3F.

FIG. 18A illustrates a circuit with an intended number of layers formed by repeated formation of wiring layers. FIG. 18B illustrates the state in which the solder resist layer 17 is applied or laminated onto the outermost layer after the formation of the circuit with the intended number of layers.

Subsequently, the solder resist layer 17 is partially removed by, for example, photolithography to form openings 18 in the solder resist layer 17 (FIG. 18C). The solder resist layer 17 is, for example, a photosensitive epoxy resin and may contain an inorganic filler. The openings 18 are formed in the solder resist layer 17 by, for example, UV or CO₂ laser irradiation or photolithography. The opening size of the opening 18 in the solder resist layer 17 for a first connection terminal area 101 may be smaller than the opening size of the opening 18 in the solder resist layer 17 for a second connection terminal area 102. The opening size of the opening 18 for the first connection terminal area 101 and the opening size of the opening 18 for the second connection terminal area 102 can be selected as appropriate.

Next, a surface-treated layer 19 is formed on the first connection pad 14 and the second connection pad 15 each within the corresponding opening 18 in the solder resist layer 17 (FIG. 18D).

Next, the first connection terminal area 101 is formed by forming a solder bump 20 over the first connection pad 14 within the opening 18 in the solder resist layer 17 (FIG. 19A). Solder bumps 20 can be formed by screen printing when soldering paste is used. When solder balls are used, after screen printing of flux, solder balls are mounted by means of ball placement and melted during reflow to form solder bumps. The second connection pad 15 is covered with any resist to prevent solder bump formation, and the resist is stripped after solder bump formation over the first connection pad 14.

Next, a new solder resist layer 17a and an opening 18a in the solder resist layer 17a are formed (FIG. 19B. In other words, the solder resist layer 17 in the first connection terminal area 101 is thinner than the solder resist layer in the second connection terminal area 102 (the solder resist layer 17 and the solder resist layer 17a). The solder resist layer in the second connection terminal area 102 (the solder resist layer 17 and the solder resist layer 17a) is obtained by stacking at least two solder resist layers, and the number of solder resist layers is greater than the number of layers constituting the solder resist layer 17 in the first connection terminal area 101. Furthermore, the second connection terminal area 102 is formed by forming a solder bump 20 over the second connection pad 15 (FIG. 19C). This process can form a wiring board 100 for mounting a semiconductor device with the first connection terminal area 101 and the second connection terminal area 102 on the semiconductor device mounting surface. Such a method for producing the wiring board 100, in other words, involves forming the solder resist layer 17 and the solder bump 20 for the first connection terminal area 101 on the outermost surface of the substrate prior to formation of the solder resist layer 17a, followed by newly forming the solder resist layer 17a and the solder bump 20 only for the second connection terminal area 102 to form the second connection terminal area 102. As described above, the first connection terminal area 101 and the second connection terminal area 102 are areas each including a solder resist layer and a solder bump.

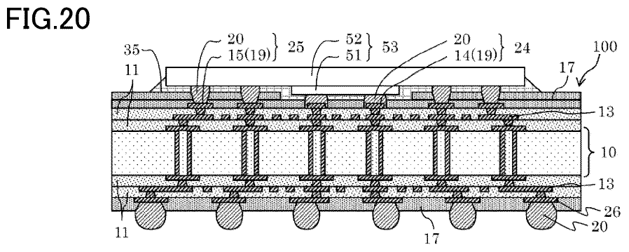

FIG. 20 is a diagram illustrating an example of a mounted state. The figure illustrates a semiconductor device obtained by mounting a 3D semiconductor device having at least two thicknesses on the wiring board 100. In this illustrated state, a 3D semiconductor device 53 (silicon chip) is mounted on the wiring board 100. This 3D semiconductor device 53 may include, for example, multiple stacked (3D-integrated) semiconductor devices or a single semiconductor device having a step in the mounting surface, with the electrode terminals electrically connected (flip-chip bonded) to the corresponding first connection terminals 24 and second connection terminals 25 on the wiring board 100 via conductive materials such as the solder bumps 20. Furthermore, the space between the mounted 3D semiconductor device 53 and the wiring board 100 is filled with an underfill resin 35 such as a thermosetting epoxy resin, and mechanical bonding is established between the 3D semiconductor device 53 and the wiring board 100 by thermal curing. In the production process, multiple unit regions for mounting 3D semiconductor devices 53 may be formed on the core substrate 10. In such a case, the unit regions are separated into individual pieces to form the wiring board 100.

The first connection terminal area 101 and the second connection terminal area 102 have different solder bump heights and solder resist layer thicknesses, as illustrated in the first connection terminal 24 and the second connection terminal 25. The solder bump 20 in the first connection terminal area 101 has a height smaller than the height of the solder bump 20 in the second connection terminal area 102.

In the illustrated 3D semiconductor device 53, a second semiconductor device 52 is mounted on a first semiconductor device 51. The wiring board 100 is electrically connected to the second semiconductor device 52 via the first connection terminal 24. The wiring board 100 is also electrically connected to the first semiconductor device 51 via the second connection terminal 25. The first semiconductor device 51 and the second semiconductor device 52 are in direct contact and electrically connected with each other.

The 3D semiconductor device 53 is composed of the first semiconductor device 51 and the second semiconductor device 52, with a single step formed in a direction perpendicular to the mounting surface. However, two or more steps may also be provided. That is, the 3D semiconductor device may be implemented by stacking two or more semiconductor devices.

Although the illustrated solder bump 20 is columnar, the shape is not limited to this. After mounting, the solder bump can be cylindrical or barrel-shaped.

Although the first semiconductor device 51 is illustrated as having a different thickness from the thickness of the second semiconductor device 52, the thicknesses of the first semiconductor device 51 and the second semiconductor device 52 can be selected as appropriate.

On the side opposite to the mounting surface for the 3D semiconductor device 53, a solder bump 20 used as an external connection terminal is formed on the part of a pad portion 26 exposed from a solder resist layer 17 after the mounting of the 3D semiconductor device 53. The wiring board 100 is mounted on, for example, a motherboard via the solder bump 20.

### Placement of Second Connection Terminal Area

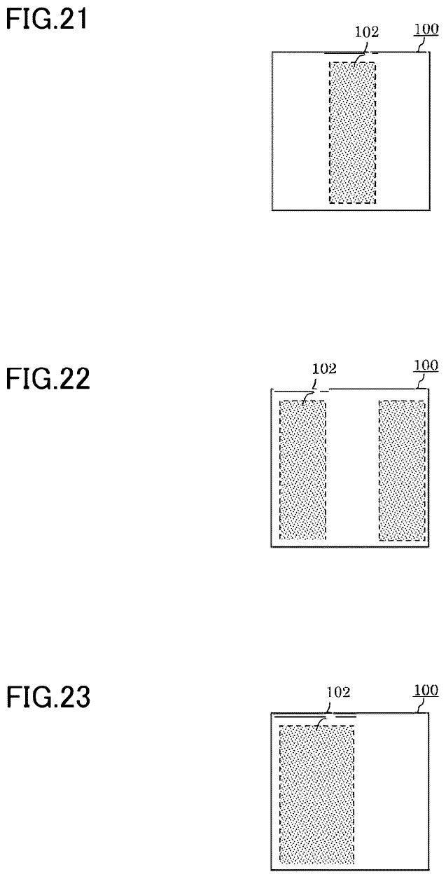

Placement examples of the second connection terminal area 102 are illustrated in FIGS. 21 to 26. FIGS. 21 to 26 are diagrams illustrating examples of the second connection terminal area according to the fifth embodiment of the present invention. FIGS. 21 to 26 are views of the wiring board 100 as seen from the semiconductor device mounting side in the mounted state.

FIG. 21 illustrates a rectangular second connection terminal area 102 placed at the central part of the wiring board 100. The second connection terminal area 102 is formed along two opposite sides of the four sides of the wiring board 100.

Note that the area of the wiring board 100 other than the second connection terminal area 102 includes the first connection terminal area 101. The same applies to FIGS. 22 to 26.

FIG. 22 illustrates a second connection terminal area 102 divided into two regions. The divided regions resulting from the second connection terminal area 102 are rectangular, and the rectangles have the same area.

FIG. 23 illustrates a second connection terminal area 102 occupying about half the area of the wiring board 100.

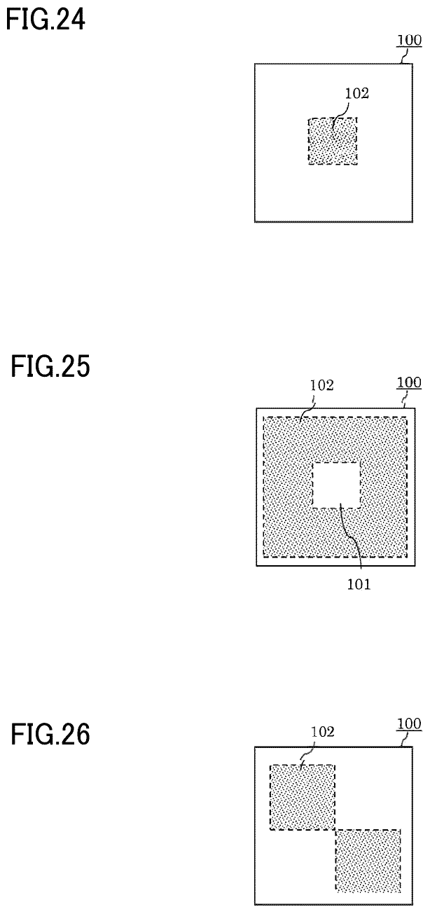

FIG. 24 illustrates a rectangular second connection terminal area 102 formed at a position coinciding with the center of gravity of the wiring board 100. The second connection terminal area 102 is geometrically similar to the wiring board 100.

FIG. 25 illustrates a second connection terminal area 102 formed to surround the region including a first connection terminal area 101.

FIG. 26 illustrates a second connection terminal area 102 divided into two regions. The two regions are rectangular and share a common vertex.

The illustrated second connection terminal areas 102 are examples, and the area can have various other forms depending on the size and shape of the 3D semiconductor device 53. For example, although the wiring board 100 is illustrated as a square, the wiring board 100 can also have non-square shapes. Furthermore, the placement of the first connection terminal area 101 and the second connection terminal area 102 may be exchanged. For example, although some Figures show a plan view illustrating the inner connection terminal area as the second connection terminal area 102 and the outer connection terminal area as the first connection terminal area 101, the outer connection terminal area may be the second connection terminal area 102, and the inner connection terminal area may be the first connection terminal area 101.

### Example 2

In Example 2, example formation of the first connection terminal 24 and the second connection terminal 25 according to the fifth embodiment is described.

First, a copper-clad laminate (manufactured by Showa Denko Materials Co., Ltd.) was laminated with an interlayer insulating resin (manufactured by Ajinomoto Co., Inc.), followed by a permanganate-based desmear process without forming a via opening.

After the desmear process, the interlayer insulating resin was covered with an electroless copper plating layer. On the electroless copper plating layer, dry film resist (manufactured by Showa Denko Materials Co., Ltd.) was laminated, exposed, and developed to form a connection pad pattern. After electrolytic copper plating, the dry film resist was stripped, and the part of the electroless copper plating layer uncovered by the electrolytic copper plating was etched to form a connection pad with a diameter of about 180 μm.

Next, the copper surface is roughened using a roughening liquid (manufactured by MEC COMPANY LTD.). After the roughening treatment, dry film solder resist (manufactured by Showa Denko Materials Co., Ltd.) is laminated under vacuum, exposed using a laser direct imaging machine, and spray developed. In this process, an opening was formed in the solder resist layer for a first connection pad portion, whereas the solder resist was removed for a second connection pad portion. This opening was formed in the solder resist layer with a bottom diameter of about 80 μm.

Next, solder balls (manufactured by Senju Metal Industry Co., Ltd.) were mounted on the first and second connection pads and reflowed to form first and second connection terminals. The solder balls have a diameter of, for example, 70 μm.

As a result of measuring the height difference between the formed first and second connection terminals using a laser interferometer, the greatest difference between the first connection terminal and the second connection terminal was about 25 μm.

### Advantages and Effects

In the wiring board 100, the second connection terminal 25 in the second connection terminal area 102 is higher than the first connection terminal 24 in the first connection terminal area 101. When semiconductor devices are mounted on the wiring board 100, with a semiconductor device mounted on the first connection terminal area 101, this structure enables another semiconductor device to be additionally mounted on the semiconductor device. In this manner, the wiring board for mounting a semiconductor device according to the present disclosure can increase the design flexibility of the 3D multilayer structure.

The solder resist layer can also block solder from adhering to unnecessary areas. The solder resist layer provided between the first connection terminal 24 and the second connection terminal 25 allows the spacing between connection terminals to be reduced compared with a structure without a solder resist layer, thus enabling a fine-pitch connection terminal pattern to be achieved. For example, with a solder resist layer provided, the width between connection terminals can be a value ranging from 45 μm to 50 μm. In contrast, with no solder resist layer provided, the width between connection terminals is a value of about 100 μm.

Embodiments of the present invention have been described. However, the present disclosure is not limited to the above embodiments and may be modified variously without departing from the spirit and scope of the present invention.

### Other Embodiments

The present disclosure also includes the following aspects.

### (Aspect 1)

A wiring board for mounting a semiconductor device, the wiring board comprising
a first connection terminal area and a second connection terminal area on a semiconductor device mounting surface, in which
the first connection terminal area includes a first connection terminal including a first connection pad and a solder bump,
the second connection terminal area includes a second connection terminal including a second connection pad and a solder bump, and
the first connection pad is covered by a solder resist layer on a side surface and a part of a top surface of the first connection pad, whereas the second connection pad is not covered by a solder resist layer on a side surface and a top surface of the second connection pad.

### (Aspect 2)

The wiring board according to aspect 1, in which
the solder bump in the first connection terminal has a height greater than a height of the solder bump in the second connection terminal on the semiconductor device mounting surface.

### (Aspect 3)

The wiring board according to aspect 1 or 2, in which
the solder bump in the first connection terminal is connected to a surface of the first connection pad, the surface being exposed through an opening in the solder resist layer, and
the solder bump in the second connection terminal is connected to a front surface and a side surface of the second connection pad.

### (Aspect 4)

The wiring board according to any one of aspects 1 to 3, in which
when the wiring board is viewed from a direction perpendicular to the semiconductor device mounting surface, the first connection pad and the second connection pad have different diameters.

### (Aspect 5)

The wiring board according to any one of aspects 1 to 4, in which
the solder resist layer on the first connection pad has an opening size different from the diameter of the second connection pad.

### (Aspect 6)

The wiring board according to any one of aspects 1 to 5, in which
the wiring board mounts a 3D semiconductor device having at least one step.

### (Aspect 7)

A method for producing the wiring board for mounting a semiconductor device according to aspect 1, characterized by
controlling height gap adjustment between the solder bump in the first connection terminal and the solder bump in the second connection terminal by the opening size of the solder resist on the first connection pad.

### (Aspect 8)

A method for producing the wiring board for mounting a semiconductor device according to aspect 1, characterized by
controlling height gap adjustment between the solder bump in the first connection terminal and the solder bump in the second connection terminal by the diameter of the second connection pad.

### (Aspect 9)

A wiring board for mounting a semiconductor device, the wiring board comprising
a first connection terminal area and a second connection terminal area on a semiconductor device mounting surface, characterized in that
the first connection terminal area and the second connection terminal area each include a solder resist layer and a solder bump, and
in the first connection terminal area and the second connection terminal area, the solder bumps have different heights, whereas the solder resist layers have different thicknesses.

### (Aspect 10)

The wiring board according to aspect 9, in which
the solder bump in the first connection terminal area has a height smaller than a height of the solder bump in the second connection terminal area.

### (Aspect 11)

The wiring board according to aspect 9 or 10, in which
the solder resist layer in the first connection terminal area has an opening size smaller than an opening size of the solder resist layer in the second connection terminal area.

### (Aspect 12)

The wiring board according to any one of aspects 9 to 11, in which
the solder resist layer in the first connection terminal area is thinner than the solder resist layer in the second connection terminal area.

### (Aspect 13)

The wiring board according to any one of aspects 9 to 12, in which
the solder resist layer in the second connection terminal area is obtained by stacking at least two solder resist layers, and the stacked solder resist layers are greater in number than stacked layers constituting the solder resist layer in the first connection terminal area.

### (Aspect 14)

The wiring board according to any one of aspects 9 to 13, in which
the first connection terminal area is an inner connection terminal area in a plan view, and the second connection terminal area is an outer connection terminal area in a plan view.

### (Aspect 15)

A semiconductor device comprising
a 3D semiconductor device having at least two thicknesses, the 3D semiconductor device being mounted on the wiring board according to any one of aspects 9 to 14.

### (Aspect 16)

A method for producing the wiring board according to any one of aspects 9 to 15,the method comprising:
in production of the wiring board, forming a solder resist layer and a solder bump for the first connection terminal area on an outermost surface of a substrate prior to formation of a solder resist layer; and
thereafter forming a new solder resist layer and a new solder bump only for the second connection terminal area to form the second connection terminal area.

Reference Signs List 1: core resin, 2: copper foil, 3: through hole, 4: hole-filling resin, 6, 16: resist pattern 8: via opening, 10: core substrate, 11: insulating resin layer, 13, 23, 33: conductor layer, 13a: seed layer, 13b: plating layer, 14: first connection pad, 15: second connection pad, 16: connection pad, 17: solder resist layer, 18: opening in solder resist layer, 19: surface-treated layer, 20: solder bump, 24: first connection terminal, 25: second connection terminal, 35: underfill resin, 43: pad portion on core substrate, 51: first semiconductor device, 52: second semiconductor device, 53: 3D semiconductor device, 100: wiring board for mounting semiconductor device, 101: first connection terminal area, 102: second connection terminal area, 124: first connection terminal area, 125: second connection terminal area, H1: height of solder bump on first connection terminal, H2: height of solder bump on second connection terminal, P1: diameter of first connection pad, P2: diameter of second connection pad, S: opening size of solder resist

What is claimed is:

1. A wiring board for mounting a semiconductor device, the wiring board comprising
a first connection terminal area and a second connection terminal area on a semiconductor device mounting surface, wherein
the first connection terminal area includes a first connection terminal including a first connection pad and a solder bump,
the second connection terminal area includes a second connection terminal including a second connection pad and a solder bump, and
the first connection pad is covered by a solder resist layer on a side surface and a part of a top surface of the first connection pad, whereas the second connection pad is not covered by a solder resist layer on a side surface and a top surface of the second connection pad.

2. The wiring board of claim 1, wherein
the solder bump in the first connection terminal has a height greater than a height of the solder bump in the second connection terminal on the semiconductor device mounting surface.

3. The wiring board of claim 1, wherein
the solder bump in the first connection terminal is connected to a surface of the first connection pad, the surface being exposed through an opening in the solder resist layer, and
the solder bump in the second connection terminal is connected to a front surface and a side surface of the second connection pad.

4. The wiring board of claim 1, wherein
when the wiring board is viewed from a direction perpendicular to the semiconductor device mounting surface, the first connection pad and the second connection pad have different diameters.

5. The wiring board of claim 1, wherein
the solder resist layer on the first connection pad has an opening size different from the diameter of the second connection pad.

6. The wiring board of claim 1, wherein
the wiring board mounts a 3D stacked semiconductor device having at least one step.

7. A method for producing the wiring board for mounting a semiconductor device of claim 1, characterized by
controlling height gap adjustment between the solder bump in the first connection terminal and the solder bump in the second connection terminal by the opening size of the solder resist on the first connection pad.

8. A method for producing the wiring board for mounting a semiconductor device of claim 1, characterized by
controlling height gap adjustment between the solder bump in the first connection terminal and the solder bump in the second connection terminal by the diameter of the second connection pad.

9. A wiring board for mounting a semiconductor device, the wiring board comprising
a first connection terminal area and a second connection terminal area on a semiconductor device mounting surface, wherein
the first connection terminal area and the second connection terminal area each include a solder resist layer and a solder bump, and
in the first connection terminal area and the second connection terminal area, the solder bumps have different heights, whereas the solder resist layers have different thicknesses.

10. The wiring board of claim 9, wherein
the solder bump in the first connection terminal area has a height smaller than a height of the solder bump in the second connection terminal area.

11. The wiring board of claim 9, wherein
the solder resist layer in the first connection terminal area has an opening size smaller than an opening size of the solder resist layer in the second connection terminal area.

12. The wiring board of claim 9, wherein
the solder resist layer in the first connection terminal area is thinner than the solder resist layer in the second connection terminal area.

13. The wiring board of claim 12, wherein
the solder resist layer in the second connection terminal area is obtained by stacking at least two solder resist layers, and the stacked solder resist layers are greater in number than stacked layers constituting the solder resist layer in the first connection terminal area.

14. The wiring board of claim 9, wherein
the first connection terminal area is an inner connection terminal area in a plan view, and the second connection terminal area is an outer connection terminal area in a plan view.

15. A semiconductor device comprising
a 3D semiconductor device having at least two thicknesses, the 3D semiconductor device being mounted on the wiring board of claim 9.

16. A method for producing the wiring board of claim 9, the method comprising:
in production of the wiring board, forming a solder resist layer and a solder bump for the first connection terminal area on an outermost surface of a substrate prior to formation of a solder resist layer; and
thereafter forming a new solder resist layer and a new solder bump only for the second connection terminal area to form the second connection terminal area.
